(19) United States
(12) Patent Application Publication
(10) Pub. No.: US 2026/0126834 A1
(43) Pub. Date: May 7, 2026

(54) ERGONOMIC SLED HANDLE

(71) Applicant: Dell Products L.P., Round Rock, TX (US)

(72) Inventors: Eduardo ESCAMILLA, Round Rock, TX (US); Bernard D. STRMISKA, Georgetown, TX (US); Amrita S. MAGUIRE, Cedar Park, TX (US)

(73) Assignee: Dell Products L.P., Round Rock, TX (US)

(21) Appl. No.: 18/935,800

(22) Filed: Nov. 4, 2024

(51) Int. Cl. G06F 1/18; H05K 5/02

(52) U.S. Cl. CPC G06F 1/181; H05K 5/023

(57) ABSTRACT

A modular information handling system may include a housing configured to house components of the information handling system and a handle assembly comprising a base mechanically coupled to a sidewall of the housing and a handle rotatably coupled to the base and configured to be mechanically translated from a closed position relative to the base to an open position relative to the base, such that, when rotated from the closed position to the open position the handle rotates inward towards a center of a front of the housing and the handle enables a person to grip the handle with a vertical wrist position.

### TECHNICAL FIELD

The present disclosure relates to modular information handling systems. More specifically, embodiments of the disclosure provide systems and methods for implementing an ergonomic sled handle for a modular information handling system.

### BACKGROUND

As the value and use of information continues to increase, individuals and businesses seek additional ways to process and store information. One option available to users is information handling systems. An information handling system generally processes, compiles, stores, and/or communicates information or data for business, personal, or other purposes thereby allowing users to take advantage of the value of the information. Because technology and information handling needs and requirements vary between different users or applications, information handling systems may also vary regarding what information is handled, how the information is handled, how much information is processed, stored, or communicated, and how quickly and efficiently the information may be processed, stored, or communicated. The variations in information handling systems allow for information handling systems to be general or configured for a specific user or specific use such as financial transaction processing, airline reservations, enterprise data storage, or global communications. In addition, information handling systems may include a variety of hardware and software components that may be configured to process, store, and communicate information and may include one or more computer systems, data storage systems, and networking systems.

Oftentimes, information handling systems are manufactured in a modular form factor and may be configured to be disposed in a chassis configured to receive such modular components. Such a chassis and its component modular information handling systems and information handling resources typically include various rails, carriers, and other mechanical components allowing for a person to add and remove the modular information handling systems from the chassis for servicing, repair, or replacement.

Modular information handling systems are often implemented as “sleds” configured to be readily inserted into or removed from a “rack” or other enclosure for holding the sleds. Such sleds often have handles to allow a user or technician to readily insert such sleds into or remove such sleds from the rack. However, existing handles are often not ergonomically-friendly. For example, in many existing approaches, sled-straddling handles may allow a user's wrist to be in an ergonomically neutral posture (e.g. vertical wrist position) with an outside grip on the handles, but such handles may be difficult to access in racks with adjacent components, such as adjacent power distribution units.

### SUMMARY

In accordance with the teachings of the present disclosure, the disadvantages and problems associated with existing approaches to inserting sleds into and removing sleds from a rack may be reduced or eliminated.

In accordance with embodiments of the present disclosure, a modular information handling system may include a housing configured to house components of the information handling system and a handle assembly comprising a base mechanically coupled to a sidewall of the housing and a handle rotatably coupled to the base and configured to be mechanically translated from a closed position relative to the base to an open position relative to the base, such that, when rotated from the closed position to the open position the handle rotates inward towards a center of a front of the housing and the handle enables a person to grip the handle with a vertical wrist position.

In accordance with these and other embodiments of the present disclosure, a handle assembly may include a base configured to mechanically couple to a sidewall of a housing configured to house components of an information handling system and a handle rotatably coupled to the base and configured to be mechanically translated from a closed position relative to the base to an open position relative to the base, such that, when rotated from the closed position to the open position the handle rotates inward towards a center of a front of the housing and the handle enables a person to grip the handle with a vertical wrist position.

In accordance with these and other embodiments of the present disclosure, a method may include rotatably coupling a handle to a base configured to mechanically couple to a sidewall of a housing configured to house components of an information handling system and configuring the handle to be mechanically translated from a closed position relative to the base to an open position relative to the base, such that, when rotated from the closed position to the open position the handle rotates inward towards a center of a front of the housing and the handle enables a person to grip the handle with a vertical wrist position.

Technical advantages of the present disclosure may be readily apparent to one skilled in the art from the figures, description and claims included herein. The objects and advantages of the embodiments will be realized and achieved at least by the elements, features, and combinations particularly pointed out in the claims.

It is to be understood that both the foregoing general description and the following detailed description are examples and explanatory and are not restrictive of the claims set forth in this disclosure.

### BRIEF DESCRIPTION OF THE DRAWINGS

A more complete understanding of the present embodiments and advantages thereof may be acquired by referring to the following description taken in conjunction with the accompanying drawings, in which like reference numbers indicate like features, and wherein:

FIG. 1 illustrates a perspective view of selected components of an example chassis for receiving modular information handling systems, in accordance with embodiments of the present disclosure;

FIG. 2 illustrates a perspective view of an example handle assembly of a modular information handling system with a handle of the handle assembly in a closed position, in accordance with embodiments of the present disclosure; and

FIG. 3 illustrates a perspective view of an example handle assembly of a modular information handling system with the handle of the handle assembly in an open position, in accordance with embodiments of the present disclosure.

### DETAILED DESCRIPTION

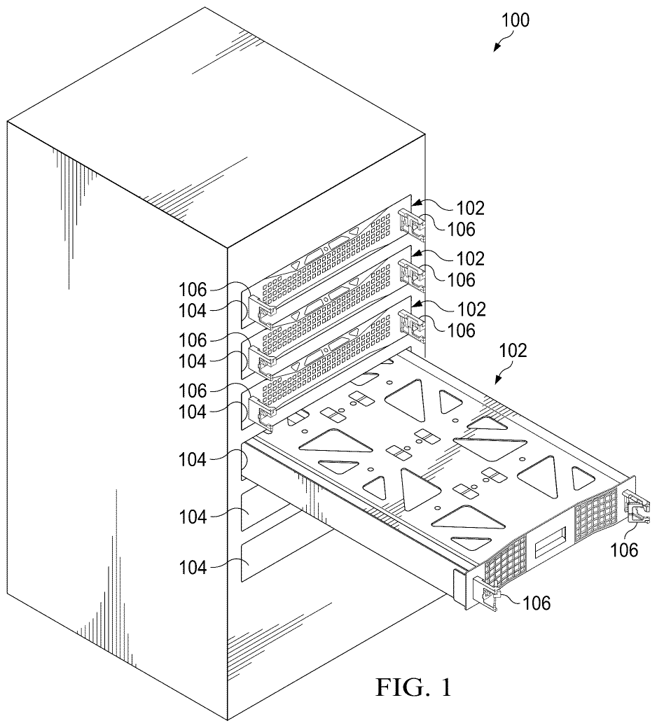

Preferred embodiments and their advantages are best understood by reference to FIGS. 1 through 3, wherein like numbers are used to indicate like and corresponding parts.

For the purposes of this disclosure, an information handling system may include any instrumentality or aggregate of instrumentalities operable to compute, classify, process, transmit, receive, retrieve, originate, switch, store, display, manifest, detect, record, reproduce, handle, or utilize any form of information, intelligence, or data for business, scientific, control, entertainment, or other purposes. For example, an information handling system may be a personal computer, a personal digital assistant (PDA), a consumer electronic device, a network storage device, or any other suitable device and may vary in size, shape, performance, functionality, and price. The information handling system may include memory, one or more processing resources such as a central processing unit (CPU) or hardware or software control logic. Additional components of the information handling system may include one or more storage devices, one or more communications ports for communicating with external devices as well as various input and output (I/O) devices, such as a keyboard, a mouse, and a video display. The information handling system may also include one or more buses operable to transmit communication between the various hardware components.

In this disclosure, the term “information handling resource” may broadly refer to any component system, device or apparatus of an information handling system, including without limitation processors, buses, memories, input-output devices and/or interfaces, storage resources, network interfaces, motherboards, electro-mechanical devices (e.g., fans), displays, and power supplies.

FIG. 1 illustrates a perspective view of selected components of an example chassis 100 for receiving modular information handling systems 102, in accordance with embodiments of the present disclosure. Chassis 100 may be an enclosure that serves as a container for various information handling systems and information handling resources, and may be constructed from steel, aluminum, plastic, and/or any other suitable material. Although the term “chassis” is used, chassis 100 may also be referred to as a rack, case, cabinet, tower, box, enclosure, and/or housing. As depicted in FIG. 1, chassis 100 may have a plurality of slots 104 each configured to receive a modular information handling system 102. As shown in FIG. 1, each modular information handling system 102 may be implemented in a sled form factor. As also shown in FIG. 1, each modular information handling system 102 may include a pair of opposing handle assemblies 106, to assist a user or technician in inserting modular information handling systems 102 into chassis 100 or removing modular information handling systems 102 from chassis 100, as described in greater detail below. Each handle assembly 106 may be formed as part of a housing of a modular information handling system 102.

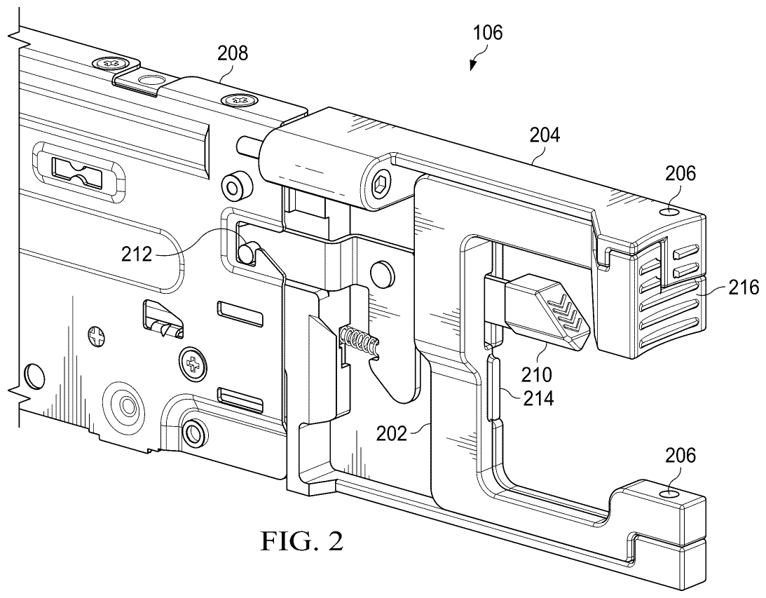

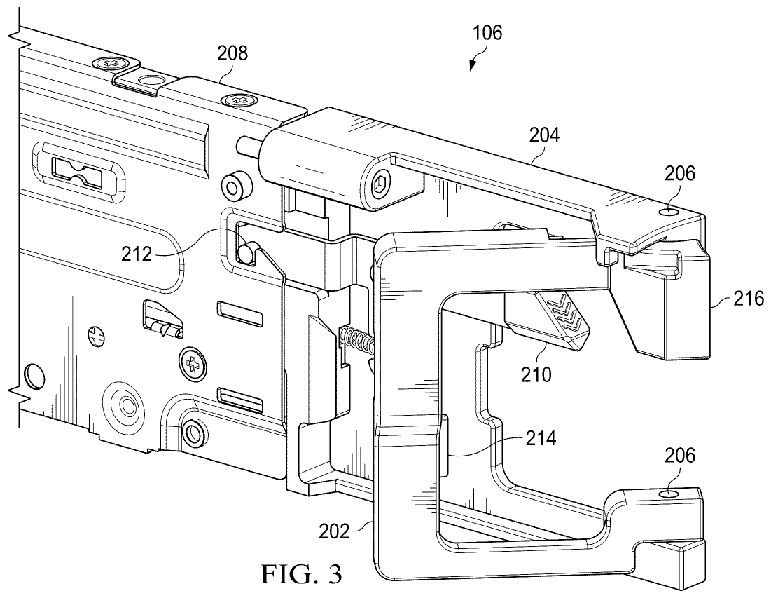

FIG. 2 illustrates a perspective view of an example handle assembly 106 with a handle 202 of handle assembly 106 in a closed position relative to a base 204 of handle assembly 106, in accordance with embodiments of the present disclosure. FIG. 3 illustrates a perspective view of example handle assembly 106 with handle 202 of handle assembly 106 in an open position relative to base 204 of handle assembly 106, in accordance with embodiments of the present disclosure.

As shown in FIGS. 2 and 3, handle assembly 202 may include handle 202 rotatably coupled to base 204 via a plurality of axes 206. Further, as shown in FIGS. 2 and 3, base 204 may be mechanically coupled to a sidewall 208 of a housing of a modular information handling system 102.

As also shown in FIGS. 2 and 3, handle assembly 106 may include a latching feature 212 configured to mechanically interact with a corresponding feature of sidewall 208 to maintain handle 202 in the closed position. To remove a modular information handling system 102 from a slot 104 of chassis 100, a user or technician may mechanically interact with a disengagement feature 210. In some embodiments, disengagement feature 210 may be a shaped coded latch to communicate its function while being an ergonomic tactile interface. Disengagement feature 210 may be mechanically coupled to latching feature 212 in order to mechanically disengage latching feature 212 from the corresponding feature of sidewall 208, thus “unlocking” handle 202. The user or technician may then mechanically interact with a touchpoint 214 extending from the interior of handle 202 that may provide the user or technician with sufficient mechanical advantage to cause rotation of handle 202 relative to base 204. In some embodiments, handle assembly 106 may be configured to allow approximately 90 degrees of rotation of handle 202 relative to base 204 from the closed position shown in FIG. 2.

Handle assemblies 106 may be arranged on a housing of a modular information handling system 102 such that as a handle 202 is rotated from the closed position to the open position relative to base 204, such rotation is “inward” towards the center of a front of the housing of the modular information handling system 102 and therefore rotates away from components adjacent to modular information handling system 102. Under such arrangement, handles 202 of opposite handle assemblies 106 of the same modular information handling system 102 may rotate towards each other as such handles 202 are rotated from the closed position to the open position relative to their respective bases 204.

When in a fully open position relative to base 204, handle 202 may enable a user or technician to grip handle 202 with an ergonomically neutral posture (e.g. vertical wrist position) in order to pull on handle 202 (or handles 202 of the same modular information handling system 102) to remove a modular information handling system 102 from chassis 100.

As further shown in FIGS. 2 and 3, handle 202 may have a surface 216 that enables a user or technician to, when handle 202 is in the closed position relative to base 204, apply force to such surface 216 to push a modular information handling system 102 into a slot 104 of chassis 102.

As used herein, when two or more elements are referred to as “coupled” to one another, such term indicates that such two or more elements are in electronic communication or mechanical communication, as applicable, whether connected indirectly or directly, with or without intervening elements.

This disclosure encompasses all changes, substitutions, variations, alterations, and modifications to the example embodiments herein that a person having ordinary skill in the art would comprehend. Similarly, where appropriate, the appended claims encompass all changes, substitutions, variations, alterations, and modifications to the example embodiments herein that a person having ordinary skill in the art would comprehend. Moreover, reference in the appended claims to an apparatus or system or a component of an apparatus or system being adapted to, arranged to, capable of, configured to, enabled to, operable to, or operative to perform a particular function encompasses that apparatus, system, or component, whether or not it or that particular function is activated, turned on, or unlocked, as long as that apparatus, system, or component is so adapted, arranged, capable, configured, enabled, operable, or operative. Accordingly, modifications, additions, or omissions may be made to the systems, apparatuses, and methods described herein without departing from the scope of the disclosure. For example, the components of the systems and apparatuses may be integrated or separated. Moreover, the operations of the systems and apparatuses disclosed herein may be performed by more, fewer, or other components and the methods described may include more, fewer, or other steps. Additionally, steps may be performed in any suitable order. As used in this document, “each” refers to each member of a set or each member of a subset of a set.

Although exemplary embodiments are illustrated in the figures and described above, the principles of the present disclosure may be implemented using any number of techniques, whether currently known or not. The present disclosure should in no way be limited to the exemplary implementations and techniques illustrated in the figures and described above.

Unless otherwise specifically noted, articles depicted in the figures are not necessarily drawn to scale.

All examples and conditional language recited herein are intended for pedagogical objects to aid the reader in understanding the disclosure and the concepts contributed by the inventor to furthering the art, and are construed as being without limitation to such specifically recited examples and conditions. Although embodiments of the present disclosure have been described in detail, it should be understood that various changes, substitutions, and alterations could be made hereto without departing from the spirit and scope of the disclosure.

Although specific advantages have been enumerated above, various embodiments may include some, none, or all of the enumerated advantages. Additionally, other technical advantages may become readily apparent to one of ordinary skill in the art after review of the foregoing figures and description.

To aid the Patent Office and any readers of any patent issued on this application in interpreting the claims appended hereto, applicants wish to note that they do not intend any of the appended claims or claim elements to invoke 35 U.S.C. § 112(f) unless the words “means for” or “step for” are explicitly used in the particular claim.

What is claimed is:

1. A modular information handling system comprising:
a housing configured to house components of the information handling system; and
a handle assembly comprising:
a base mechanically coupled to a sidewall of the housing; and
a handle rotatably coupled to the base and configured to be mechanically translated from a closed position relative to the base to an open position relative to the base, such that, when rotated from the closed position to the open position:
the handle rotates inward towards a center of a front of the housing; and
the handle enables a person to grip the handle with a vertical wrist position.

2. The modular information handling system of claim 1, wherein the handle further comprises a touchpoint extending from an interior of the handle that provides the person a mechanical advantage to cause the handle to rotate relative to the base.

3. The modular information handling system of claim 1, wherein the handle assembly further comprises a latching feature configured to mechanically interact with a corresponding feature of the sidewall to maintain the handle in the closed position.

4. The modular information handling system of claim 3, wherein the handle assembly further comprises a disengagement feature mechanically coupled to the latching feature and configured to enable the person to mechanically interact with the disengagement feature to mechanically disengage the latching feature from the corresponding feature.

5. The modular information handling system of claim 1, wherein the handle further comprises a surface configured such that when the handle is in the closed position, the surface enables the person to apply a mechanical force to the surface to insert the modular information handling system into the chassis.

6. A handle assembly comprising:
a base configured to mechanically couple to a sidewall of a housing configured to house components of an information handling system; and
a handle rotatably coupled to the base and configured to be mechanically translated from a closed position relative to the base to an open position relative to the base, such that, when rotated from the closed position to the open position:
the handle rotates inward towards a center of a front of the housing; and
the handle enables a person to grip the handle with a vertical wrist position.

7. The handle assembly of claim 6, wherein the handle further comprises a touchpoint extending from an interior of the handle that provides the person a mechanical advantage to cause the handle to rotate relative to the base.

8. The handle assembly of claim 6, further comprising a latching feature configured to mechanically interact with a corresponding feature of the sidewall to maintain the handle in the closed position.

9. The handle assembly of claim 8, further comprising a disengagement feature mechanically coupled to the latching feature and configured to enable the person to mechanically interact with the disengagement feature to mechanically disengage the latching feature from the corresponding feature.

10. The handle assembly of claim 6, wherein the handle further comprises a surface configured such that when the handle is in the closed position, the surface enables the person to apply a mechanical force to the surface to insert the modular information handling system into the chassis.

11. A method comprising:
rotatably coupling a handle to a base configured to mechanically couple to a sidewall of a housing configured to house components of an information handling system; and
configuring the handle to be mechanically translated from a closed position relative to the base to an open position relative to the base, such that, when rotated from the closed position to the open position:
the handle rotates inward towards a center of a front of the housing; and
the handle enables a person to grip the handle with a vertical wrist position.

12. The method of claim 11, further comprising forming a touchpoint extending from an interior of the handle that provides the person a mechanical advantage to cause the handle to rotate relative to the base.

13. The method of claim 11, further comprising providing a latching feature configured to mechanically interact with a corresponding feature of the sidewall to maintain the handle in the closed position.

14. The method of claim 13, further comprising mechanically coupling a disengagement feature to the latching feature and configuring the disengagement feature to enable the person to mechanically interact with the disengagement feature to mechanically disengage the latching feature from the corresponding feature.

15. The method of claim 11, further comprising forming a surface on the handle and configuring the surface such that when the handle is in the closed position, the surface enables the person to apply a mechanical force to the surface to insert the modular information handling system into the chassis.
